(19) United States
(12) Patent Application Publication
(10) Pub. No.: US 2006/0079067 A1
(43) Pub. Date: Apr. 13, 2006

(54) Methods for aligning patterns on a substrate based on optical properties of a mask layer and related devices

(75) Inventors: Jang-Ho Shin, Seoul (KR); Suk-Joo Lee, Seoul (KR); Han-Ku Cho, Gyeonggi-do (KR); Sang-Gyun Woo, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/235,607

(22) Filed: Sep. 26, 2005

(30) Foreign Application Priority Data
Oct. 11, 2004 (KR) 10-2004-0080996

(51) Int. Cl. H01L 21/76; H01L 21/78; H01L 21/66

(52) U.S. Cl. 438/401; 438/462; 438/975; 438/16

(57) ABSTRACT

A method of fabricating a semiconductor device includes forming a material layer on a substrate, forming a mask layer on the material layer, and implanting ions into the mask layer to reduce light absorption thereof. An alignment key may be formed between the material layer and the substrate, and a location of the alignment key may be optically determined through the implanted mask layer. The implanted mask layer is patterned to define a mask pattern, and the material layer is patterned using the mask pattern as an etching mask. Related devices are also discussed.

### CROSS-REFERENCE TO RELATED APPLICATIONS

This application claims priority under 35 U.S.C. § 119 from Korean Patent Application 10-2004-0080996 filed on Oct. 11, 2004, the disclosure of which is hereby incorporated by reference herein in its entirety.

### FIELD OF THE INVENTION

The present invention relates to semiconductor device fabrication, and more particularly, to methods of aligning patterns in semiconductor device fabrication.

### BACKGROUND OF THE INVENTION

Semiconductor devices may include an integrated structure of multilayered patterns. Accordingly, patterns formed on different layers may require alignment therebetween within a limited margin of error. Many methods for measuring alignment between patterns are known. Generally, a location of an alignment key formed on a pattern may be optically determined, and an overlap of an upper and a lower alignment key may be measured.

As semiconductor devices are scaled down, pattern widths may become smaller, and photolithography techniques using a light source with a relatively short wavelength may be required to define such patterns. Also, in order to increase precision and accuracy in forming patterns, a relatively thin photoresist pattern may be used during a photolithography process employing a relatively short wavelength light source. However, as such a relatively thin photoresist layer may not provide an adequate etching mask where a material to be etched is relatively thick, a hard mask layer having an etch selectivity with respect to the material to be etched may be used.

FIGS. 1 to 3 are views illustrating conventional methods for patterning a semiconductor device.

Referring to FIG. 1, a material layer 12 may be formed on a substrate 10, and a hard mask layer and a photoresist layer may be formed on the material layer 12. The hard mask layer may include an organic hard mask layer 14 (which may be easily patterned and/or may have relatively good etch selectivity with respect to a lower material layer), and an inorganic hard mask layer 16 (which may be used as an etching mask for the organic hard mask layer 14). The photoresist layer may be exposed and developed to form a photoresist pattern 18.

Referring to FIG. 2, the inorganic hard mask layer 16 may be patterned using the photoresist pattern 18 as an etching mask to form the inorganic hard mask pattern 16p, and the photoresist pattern 18 may be removed. The organic hard mask layer 14 may be patterned using the inorganic hard mask pattern 16p as an etching mask to form an organic hard mask pattern 14p.

Referring to FIG. 3, the material layer 12 may be patterned using the inorganic hard mask pattern 16p and/or the organic hard mask pattern 14p as an etching mask to form a material layer pattern 12p. The material layer pattern 12p may itself form a desired pattern, or may be used as a cast/mold for forming the other patterns. The inorganic hard mask pattern 16p may be etched in forming the material layer pattern 12p, and/or a part of the inorganic hard mask pattern 14r may be etched. The material layer pattern 12p may be used in a process for forming a storage node of a DRAM device. In other words, the material layer pattern 12p may define an opening where a storage node may be formed.

A pattern formed in a subsequent process may require alignment with a pattern formed in a prior process within a predetermined margin of error. Accordingly, an overlay mark for measuring an overlap between upper and lower patterns, i.e., an alignment key, may be formed together with a pattern at a predetermined region of a substrate. As shown in FIG. 4, a pattern region 62 on a photomask 60 may be irradiated on a substrate, for example, using a photolithography process. More particularly, the photomask 60 may be exposed to a light source such that the pattern region 62 may be formed on a chip region 52 formed during a prior process. To do so, an alignment key 54 (which may have already been formed at a chip region of the substrate) and an alignment key 64 on the photomask 60 may be aligned with one another. In addition, after photolithography is completed, locations of the alignment key 54 and the alignment key 64 may be measured, and their degree of overlap may be confirmed. An etching process may be performed if the overlap is within a predetermined margin of error.

FIG. 5 is a plan view illustrating conventional alignment keys. The alignment keys may be used to measure a degree of overlap between patterns, and may be formed to have various shapes according to a particular alignment method. As shown in FIG. 5, the alignment key may include a first alignment key 70a on an earlier-formed pattern and a second alignment key 70b on a later-formed pattern. The second alignment key 70b may be designed on a photomask prior to photolithography, and may be formed on a substrate after a photolithography. Relative locations of the alignment keys may be measured based on dispersion of light at an interface of the keys. The horizontal distances d1 and d2 between the first alignment key 70a and the second alignment key 70b may be compared to calculate an overlap in a horizontal direction, and the vertical distances d3 and d4 may be compared to calculate an overlap in a vertical direction.

As shown in FIG. 6, if a surface of the material layer 12 covering a first alignment key 20a follows the contours of the shape of the first alignment key 20a, it may be possible to measure distances d and d′ from the second alignment key 20b by measuring light dispersed at an interface or step difference in the material layer 12 due to the first alignment key 20a. As shown in FIGS. 7 and 8, where a material layer 12 covering a first alignment key 20a is planarized and an opaque organic hard mask layer 14 is formed thereon, it may be difficult to measure a location of the alignment key 20a, as light may not penetrate the organic hard mask layer 14. Thus, even after a second alignment key 20b is formed by etching a photoresist layer 18, it may be difficult to measure a location of the first alignment key 20a.

### SUMMARY OF THE INVENTION

According to some embodiments of the present invention, a method for measuring an alignment may include forming a first alignment key on a substrate, forming a material layer covering the first alignment key, forming an opaque mask layer on the material layer, performing an ion implantation process on the opaque layer to reduce a light absorption coefficient of the opaque layer, forming a photoresist layer on the opaque layer, and transmitting light through the opaque layer having the reduced light absorption coefficient.

In some embodiments, a planarized material layer may be formed on the first alignment key. The opaque layer may be an organic hard mask layer, such as an amorphous carbon layer. An inorganic hard mask layer may be further formed between the opaque layer and the photoresist layer.

In other embodiments, a location of the alignment key may be measured when a photomask is arranged on a substrate and/or after a photoresist pattern is formed. For example, a location of the first alignment key may be measured to align a photomask on a substrate, and the photoresist may be exposed to a light using the photomask. In another example, the exposed photoresist may be developed to form a photoresist pattern including a second alignment key, and the location of the first alignment key and the second alignment key may be measured to determine an alignment of the photoresist pattern.

According to further embodiments of the present invention, a method of fabricating a semiconductor device may include forming a material layer on a substrate and forming a mask layer on the material layer. For example, the mask layer may be an opaque mask layer, such as an amorphous carbon layer Ions may be implanted into the mask layer to reduce light absorption thereof. The implanted mask layer may be patterned to define a mask pattern, and the material layer may be patterned using the mask pattern as an etching mask.

In some embodiments, the mask layer may be an organic mask layer. In addition, an inorganic mask layer may be formed on the organic mask layer prior to implanting the ions. The ions may be implanted into the organic mask layer through the inorganic mask layer.

In other embodiments, nitrogen ions may be implanted into the mask layer to reduce light absorption thereof. For example, nitrogen ions having a nitrogen concentration of about 5×10¹⁵ ions/cm² may be implanted into the mask layer.

In some embodiments, an alignment key may be formed between the material layer and the substrate. A location of the alignment key may be optically determined through the implanted mask layer after the ions are implanted therein. A photomask may be aligned with the substrate using the alignment key before patterning the implanted mask layer.

In other embodiments, the material layer may be planarized prior to forming the mask layer thereon.

In some embodiments, a second alignment key may be formed on the implanted mask layer after implanting the ions and before patterning the implanted mask layer. An alignment of the second alignment key may be measured based on the location of the first alignment key. The material layer may be patterned using the mask pattern as an etching mask if the alignment is within a predetermined margin of error. In some embodiments, the mask pattern may be removed after patterning the material layer.

In other embodiments, the alignment may be measured by transmitting a light through the implanted mask layer. The light may have a wavelength of about 600 nm to about 700 nm, and the mask layer may have a light absorption coefficient in a range of about 0.35 to about 0.4. Relative locations of the first and second alignment keys may be determined based on the transmitted light.

In some embodiments, a photoresist pattern may be formed on a portion of the mask layer. The ions may be implanted into a portion of the mask layer that is exposed by the photoresist pattern.

In some embodiments, the mask layer may be formed at a temperature of about 500° C. to about 600° C. In other embodiments, the mask layer may be formed to a thickness of about 150 Å to about 250 Å.

According to other embodiments of the present invention a method of aligning patterns on a substrate may include forming a first alignment key on the substrate, forming a material layer on the first alignment key, and forming a mask layer on the material layer. Ions may be implanted into the mask layer, for example, to reduce light absorption of the mask layer. A second alignment key may also be formed on the mask layer. Relative locations of the first and second alignment keys may be optically determined through the mask layer after implanting the ions therein.

According to still further embodiments of the present invention, a semiconductor device may include a substrate, an alignment key on the substrate, a material layer on the alignment key, and an amorphous carbon mask layer on the material layer. The amorphous carbon mask layer may include nitrogen therein. For example, the amorphous carbon mask layer may have a nitrogen concentration of about 5×10¹⁵ ions/cm².

In some embodiments, the amorphous carbon mask layer may have a thickness of about 150 Å to about 250 Å. The amorphous carbon mask layer may also have a light absorption coefficient in a range of about 0.35 to about 0.4 with respect to light having a wavelength of about 600 nm to about 700 nm.

In other embodiments, the material layer may be a planarized material layer. The device may further include a second alignment key on the amorphous carbon mask layer. The second alignment key may be aligned with the first alignment key within a predetermined margin of error.

### BRIEF DESCRIPTION OF THE DRAWINGS

FIGS. 1 to 3 are cross-sectional views illustrating conventional methods for patterning a semiconductor substrate;

FIG. 4 is a plan view illustrating a conventional alignment process;

FIG. 5 is a plan view illustrating conventional alignment keys;

FIGS. 6 to 8 are cross-sectional views illustrating conventional methods for aligning patterns on a substrate;

FIGS. 9A-B, 10A-B, and 11 are cross-sectional views illustrating methods for aligning patterns on a substrate in accordance with some embodiments of the present invention; and

FIG. 12 is a graph illustrating light absorption of a mask layer used in methods of aligning patterns on a substrate in accordance with some embodiments of the present invention.

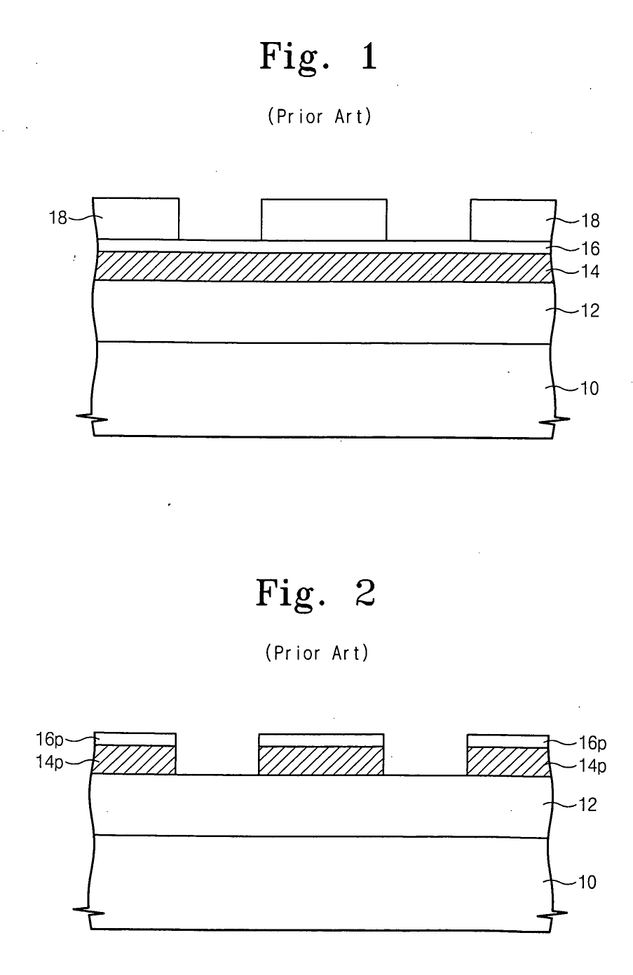

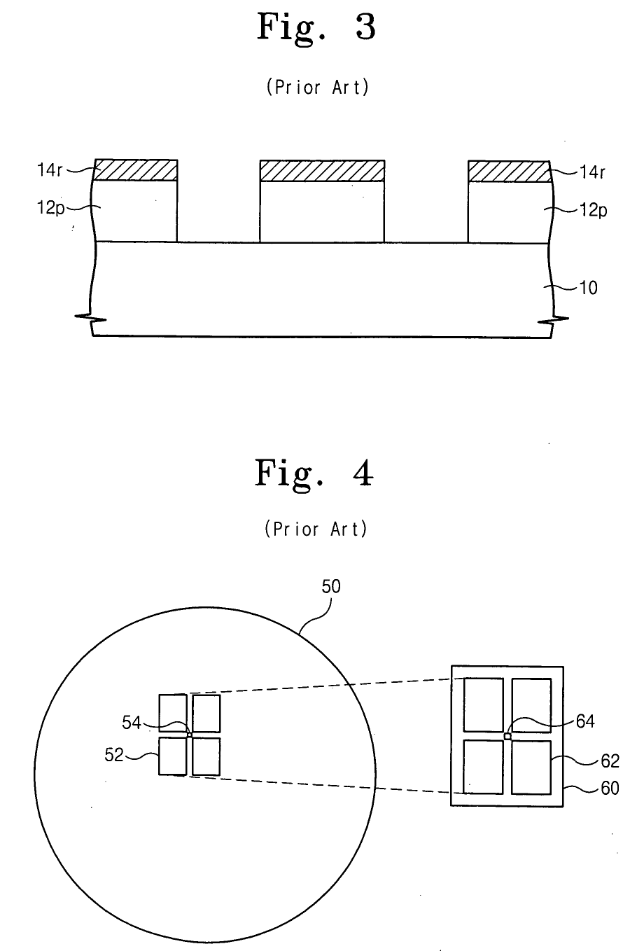

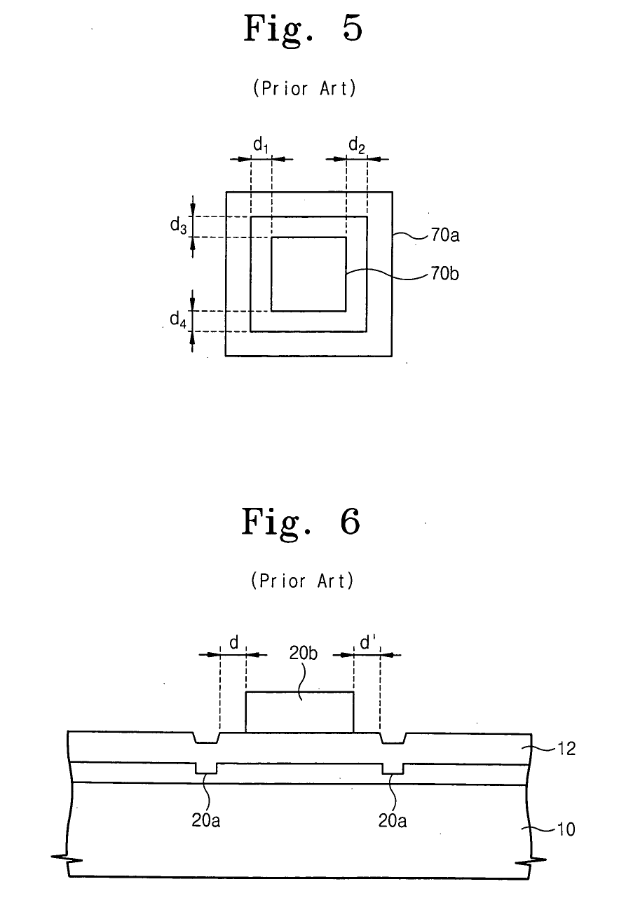

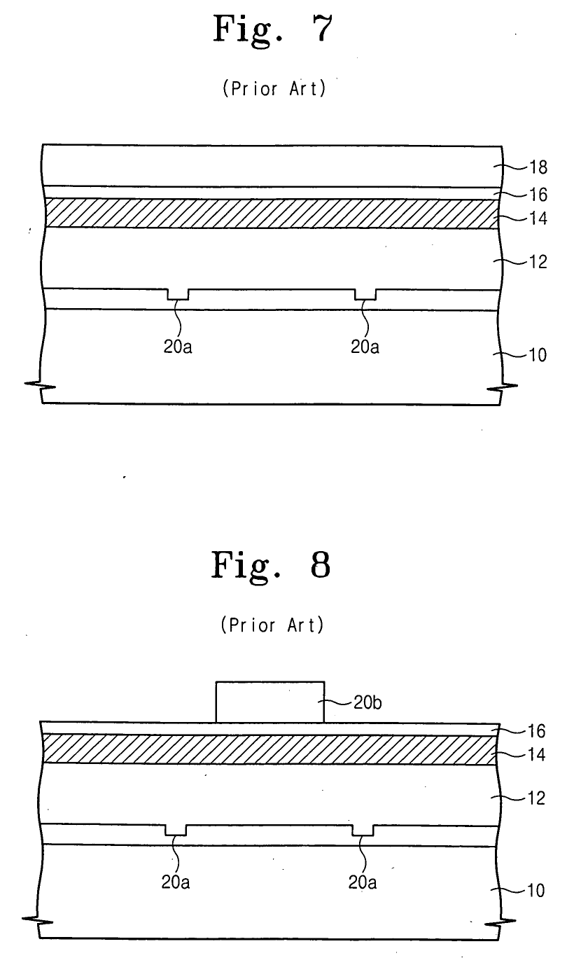

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

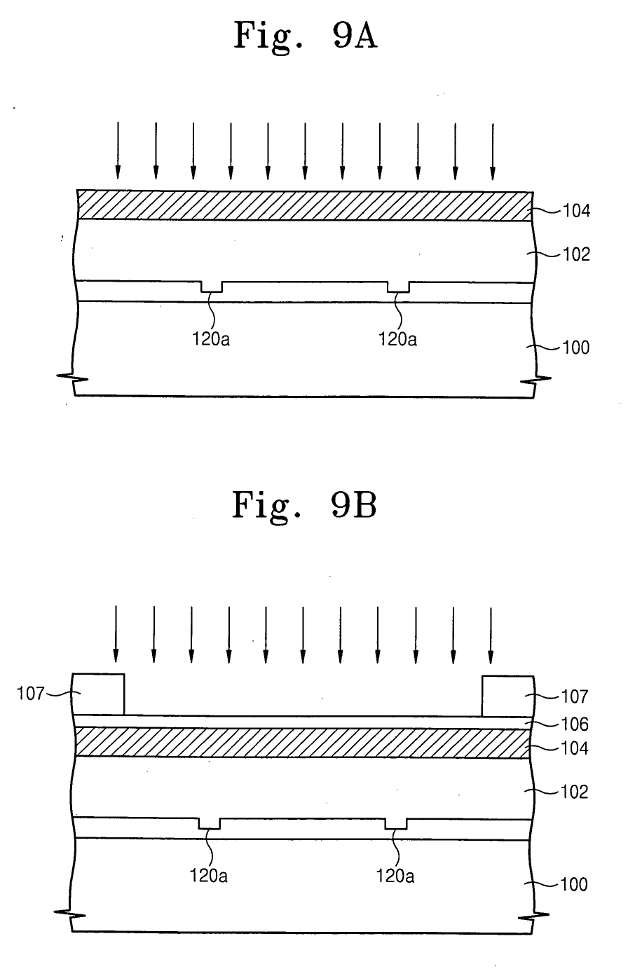

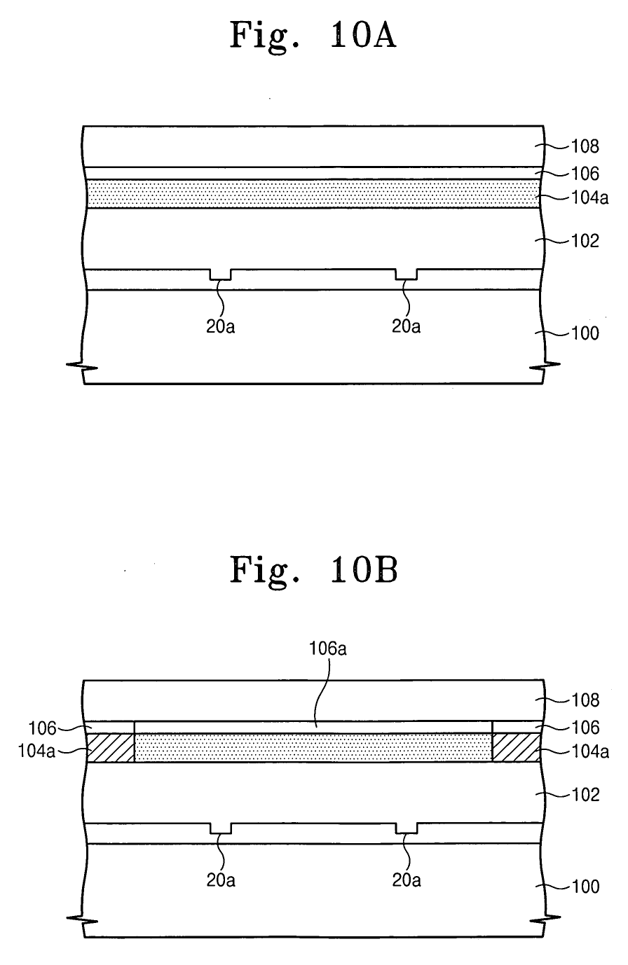

FIGS. 9A, 9B, 10A, 10B and 11 are cross-sectional views illustrating methods of aligning patterns on a substrate in accordance with some embodiments of the present invention.

Referring now to FIG. 9A, a material layer 102 is formed on the substrate 100 on which a first alignment key 120a is formed, and an organic hard mask layer 104 is formed on the material layer 102. A conventional alignment measuring device may employ a light source with a wavelength ranging from about 600 nm to about 700 nm to measure alignment. The organic hard mask layer 104 may be formed of an amorphous carbon layer having relatively good etch selectivity with respect to the material layer 102. As the organic hard mask layer 104 may have a relatively high light absorption coefficient, a relatively thin organic hard mask layer 104 may be required to measure alignment. However, to provide an adequate etching mask with respect to the material layer 102, a relatively thick organic hard mask layer 104 may be required. As such, the thickness of the organic hard mask layer 104 may be determined based on its intended use. In other words, the organic hard mask layer 104 may not be formed beyond a maximum thickness for use in an alignment process, and may not be formed beyond a minimum thickness for use as an etching mask.

As the temperature at which the organic hard mask layer 104 is formed is increased, a light absorption coefficient of the organic hard mask layer 104 may also be increased. Accordingly, the organic hard mask layer 104 may be formed at a relatively low temperature to reduce its light absorption coefficient. However, an organic hard mask layer 104 formed at lower temperatures may have a relatively high hydrogen concentration, and consequently, may have a relatively low etch resistance. As such, the organic hard mask layer 104 may need to be formed at a temperature of at least 500° C. to adequately function as an etching mask.

According to some embodiments of the present invention, an organic hard mask layer 104 may be formed at a temperature ranging from about 500° C. to about 600° C. As such, the organic hard mask layer 104 may be an opaque layer having a relatively high light absorption coefficient and a relatively high etch resistance. For example, the organic hard mask layer may be an amorphous carbon layer formed using a source gas such as hydro-carbon CₓH_{y}, and a reaction gas such as hydrogen, nitrogen and/or ammonia.

The light absorption coefficient of the organic hard mask 104 may be reduced using an ion implantation process. For example, nitrogen ions having a concentration of about 10¹⁵ ions/cm² may be implanted into the organic hard mask layer 104 to lower the light absorption coefficient thereof with respect to an alignment measurement light source having a wavelength ranging from, for example, about 600 nm to about 700 nm.

In order to provide an adequate etch mask for patterning lower material layers, the organic hard mask layer 104 may be formed to a thickness ranging from about 150 Angstroms (Å) to about 250 Å. By implanting ions into the organic hard mask layer 104, a light absorption coefficient of the organic hard mask layer 104a may be reduced to a range of about 0.35 to about 0.40. As such, light may be transmitted through the organic hard mask layer 104a to reach the first alignment key 120a.

Referring to FIG. 10A, an inorganic hard mask layer 106 is formed on the organic hard mask layer 104a after the light absorption coefficient thereof has been lowered by the ion implantation process. A photoresist layer 108 is formed on the inorganic hard mask layer 106. The photoresist layer 108 may include a reflection prevention layer at a lower portion thereof. An alignment process is performed to align a photomask (including a pattern thereon) with the substrate 100 on which the photoresist layer 108 is formed. As the organic hard mask layer 104a has a relatively low light absorption coefficient with respect to the light source described above, a location of the first alignment key 120a can be determined, and an overlap of the first alignment key 120a and a second alignment key on the photomask may be measured to align the photomask on the substrate 100. However, if the photomask is aligned based on a location of an alignment key on the photomask and a predetermined input coordinate, measurement of the overlap of the alignment key on the substrate and the alignment key on the photomask may be omitted.

Referring to FIG. 11, a photolithography process is performed using the photomask aligned on the photoresist layer 108 on the substrate to form a photoresist pattern. The photoresist pattern includes a second alignment key 120b. If an overlap between the second alignment key 120b and the first alignment key 120a exceeds a predetermined margin of error, a rework may be required.

In contrast, if an overlap of the photoresist pattern is within the margin of error, the hard mask layer 104a and the material layer 102 are etched using the photoresist pattern as an etching mask.

FIGS. 9B and 10B are cross-sectional views illustrating methods of aligning patterns on a substrate according to further embodiments of the present invention.

As shown in FIG. 9B, an ion implantation process is performed on the organic hard mask layer 104 to reduce light absorption, as described above. However, in contrast to the embodiments illustrated in FIG. 9A, the ion implantation process is performed after the inorganic hard mask layer 106 is formed on the organic hard mask layer 104. In other words, ions are implanted into the organic hard mask layer 104 through the inorganic hard mask layer 106. The ion implantation process may be prevented at regions other than the alignment key region by forming a photoresist pattern 107 thereon.

Referring to FIG. 10B, due to the ion implantation process, an ion implantation layer 106a may be formed at a portion of the inorganic hard mask layer 106 on the alignment key region. However, as light may be transmitted through the implanted mask layers 106a and 104a, a location of a first alignment key can be determined.

As described above, when an opaque hard mask layer having a relatively good etch selectivity with respect to a lower material layer is used in a patterning process, a light absorption coefficient of the opaque hard mask layer can be lowered by implanting ions into the opaque hard mask layer. As a result, even if one or more lower layers are planarized, a location of an alignment key can be determined because light may be transmitted through the implanted hard mask layer to the alignment key.

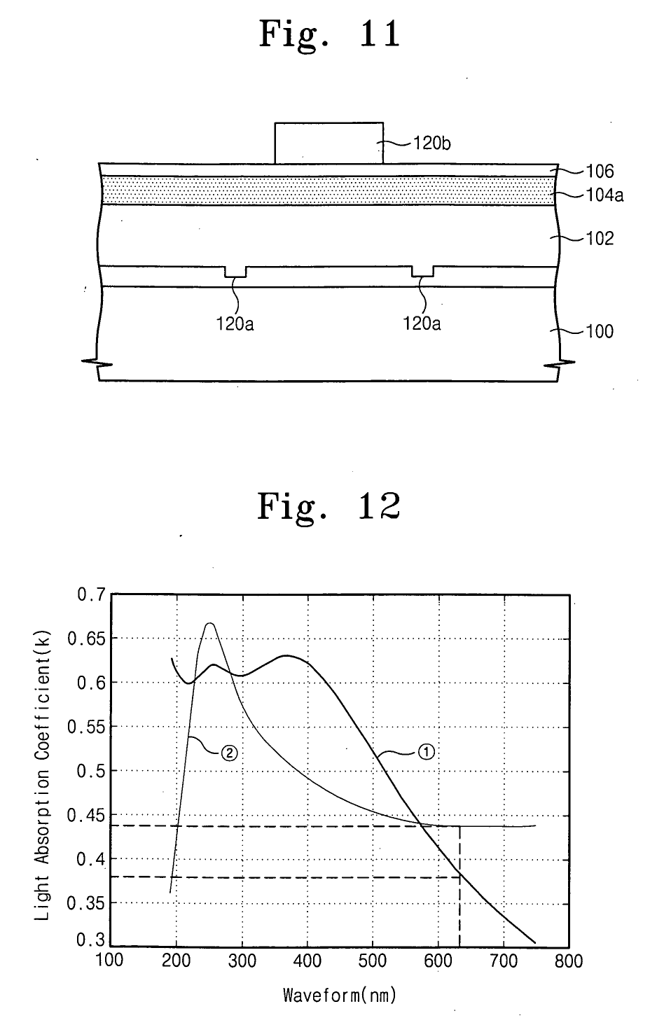

FIG. 12 is a graph illustrating effects of ion implantation on light absorption of an organic hard mask layer according to some embodiments of the present invention. The graph shows the results obtained from implanting nitrogen ions having a concentration of about 5×10¹⁵ ion/cm² into an amorphous carbon layer at 550° C. under 50 keV energy (line (\textcircled{1}). The graph also illustrates light absorption in an amorphous carbon layer formed under similar conditions, but into which nitrogen ions have not been implanted (line (\textcircled{2}).

As shown in FIG. 12, the light absorption coefficient of an organic hard mask layer may be altered when ion implantation is performed (line (\textcircled{1}), as compared to when ion implantation is not performed (line (\textcircled{2}). More particularly, a mask layer into which ions are implanted may have a light absorption coefficient of about 0.35 to about 0.40 for a light source with a wavelength ranging from about 600 nm to about 700 nm, while a mask layer into which ions are not implanted may have a light absorption coefficient of about 0.45.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

That which is claimed:

1. A method of fabricating a semiconductor device, the method comprising:
forming a material layer on a substrate;
forming a mask layer on the material layer;
implanting ions into the mask layer to reduce light absorption thereof;
patterning the implanted mask layer to define a mask pattern; and
patterning the material layer using the mask pattern as an etching mask.

2. The method of claim 1, wherein the mask layer comprises an organic mask layer.

3. The method of claim 2, further comprising:
forming an inorganic mask layer on the organic mask layer prior to implanting the ions,
wherein implanting the ions comprises implanting the ions into the organic mask layer through the inorganic mask layer.

4. The method of claim 1, wherein the mask layer comprises an amorphous carbon layer.

5. The method of claim 1, wherein implanting the ions comprises:
implanting nitrogen ions into the mask layer to reduce light absorption thereof.

6. The method of claim 5, wherein implanting the nitrogen ions comprises:
implanting nitrogen ions having a nitrogen concentration of about 5×10¹⁵ ions/cm².

7. The method of claim 1, further comprising:
forming an alignment key between the material layer and the substrate; and
optically determining a location of the alignment key through the implanted mask layer after implanting the ions therein.

8. The method of claim 7, further comprising:
planarizing the material layer prior to forming the mask layer thereon.

9. The method of claim 7, further comprising the following after implanting the ions and before patterning the implanted mask layer:
aligning a photomask with the substrate using the alignment key.

10. The method of claim 7, further comprising the following after implanting the ions and before patterning the implanted mask layer:
forming a second alignment key on the implanted mask layer; and
measuring an alignment of the second alignment key based on the location of the first alignment key.

11. The method of claim 10, wherein measuring the alignment comprises:
transmitting light through the implanted mask layer; and
determining relative locations of the first and second alignment keys based on the transmitted light.

12. The method of claim 11, wherein the light has a wavelength of about 600 nm to about 700 nm, and wherein the mask layer has a light absorption coefficient in a range of about 0.35 to about 0.4.

13. The method of claim 10, wherein patterning the material layer comprises:
etching the material layer using the mask pattern as an etching mask if the alignment is within a predetermined margin of error.

14. The method of claim 1, further comprising:
forming a photoresist pattern on a portion of the mask layer,
wherein implanting the ions comprises implanting the ions into a portion of the mask layer exposed by the photoresist pattern.

15. The method of claim 1, wherein forming the mask layer comprises:
forming the mask layer at a temperature of about 500° C. to about 600° C.

16. The method of claim 1, wherein forming the mask layer comprises:
forming the mask layer to a thickness of about 150 Å to about 250 Å.

17. The method of claim 1, further comprising:
removing the mask pattern after patterning the material layer.

18. A method of aligning patterns on a substrate, comprising:
forming a first alignment key on the substrate;
forming a material layer on the first alignment key;
forming a mask layer on the material layer;
implanting ions into the mask layer;
forming a second alignment key on the mask layer; and
optically determining relative locations of the first and second alignment keys through the mask layer after implanting the ions therein.

19. A semiconductor device, comprising:
a substrate;
an alignment key on the substrate;
a planarized material layer on the alignment key; and
an amorphous carbon mask layer including nitrogen therein on the material layer.

20. The device of claim 19, wherein the amorphous carbon mask layer has a nitrogen concentration of about 5×10¹⁵ ions/cm².

21. The device of claim 19, wherein the amorphous carbon mask layer has a thickness of about 150 Å to about 250 Å and has a light absorption coefficient in a range of about 0.35 to about 0.4 with respect to light having a wavelength of about 600 nm to about 700 nm.

22. The device of claim 19, further comprising:
a second alignment key on the amorphous carbon mask layer and aligned with the first alignment key within a predetermined margin of error.
